(19) United States
(12) Patent Application Publication
(10) Pub. No.: US 2009/0142693 A1
(43) Pub. Date: Jun. 4, 2009

(54) NEGATIVE RESIST COMPOSITION AND METHOD OF FORMING RESIST PATTERN

(75) Inventor: Jun Iwashita, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: TOKYO OHKA KOGYO CO., LTD., Kawasaki-shi (JP)

(21) Appl. No.: 11/813,667

(22) PCT Filed: Jan. 11, 2006
(86) PCT No.: PCT/JP2006/300222

§ 371 Date: Jul. 10, 2007

(30) Foreign Application Priority Data
Jan. 12, 2005 (JP) 2005-005013

(51) Int. Cl. G03F 7/004; G03F 7/20

(52) U.S. Cl. 430/270.1; 430/325

(57) ABSTRACT

A negative resist composition and a method of forming a resist pattern that are capable of suppressing resist pattern swelling are provided. The negative resist composition includes an alkali-soluble resin component (A), an acid generator component (B) that generates acid upon exposure, and a cross-linking agent component (C), wherein the alkali-soluble resin component (A) is a copolymer (A1) that includes a structural unit (a1) containing, within the main chain, an aliphatic cyclic group having a fluorinated hydroxyalkyl group, a structural unit (a2) derived from an acrylate ester which contains a hydroxyl group-containing chain-like or cyclic alkyl group and has a fluoroalkyl group or fluorine atom bonded to the α-position, and a structural unit (a3) derived from an acrylate ester which contains an aliphatic cyclic group having a fluorinated hydroxyalkyl group and has a fluoroalkyl group or fluorine atom bonded to the α-position.

### TECHNICAL FIELD

The present invention relates to a negative resist composition and a method of forming a resist pattern.

Priority is claimed on Japanese Patent Application No. 2005-005013, filed Jan. 12, 2005, the content of which is incorporated herein by reference.

### BACKGROUND ART

In recent years, in the production of semiconductor elements and liquid crystal display elements, advances in lithography techniques have lead to rapid progress in the field of miniaturization. Typically, these miniaturization techniques involve shortening the wavelength of the exposure light source. Conventionally, ultraviolet radiation typified by g-line and i-line radiation has been used, but nowadays KrF excimer lasers (248 nm) are the main light source used in mass production, and ArF excimer lasers (193 nm) are now also starting to be introduced in mass production. Furthermore, research is also being conducted into lithography techniques that use F₂ excimer lasers (157 nm), EUV (extreme ultra violet radiation), and EB (electron beams) and the like as the light source (radiation source).

Resists for use with these types of short wavelength light sources require a high resolution capable of reproducing patterns of minute dimensions, and a high level of sensitivity relative to these types of short wavelength light sources. One example of a known resist that satisfies these conditions is a chemically amplified resist, which includes a base resin and an acid generator that generates acid upon exposure, and these chemically amplified resists include positive resists in which the alkali solubility of the exposed portions increases, and negative resists in which the alkali solubility of the exposed portions decreases.

Conventionally, negative resist compositions for use in processes that use either i-line radiation or a KrF excimer laser (248 nm) as the light source have employed negative resist compositions containing a combination of an acid generator, an alkali-soluble resin such as a novolak resin or a polyhydroxystyrene, and an amino resin such as a melamine resin or urea resin (for example, see patent reference 1).

Furthermore, negative resist compositions that can be applied to processes that use an ArF excimer laser of even shorter wavelength have also been proposed (for example, see non-patent references 1 to 3 and patent reference 2).

For example, a negative resist composition that includes a resin component containing carboxyl groups, a cross-linking agent containing alcoholic hydroxyl groups, and an acid generator has been proposed. In this composition, the action of the acid generated from the acid generator causes the carboxyl groups within the resin component to react with the alcoholic hydroxyl groups of the cross-linking agent, causing the resin component to change from an alkali-soluble state to an alkali-insoluble state.

Furthermore, compositions have also been proposed which include a resin component containing carboxyl groups or carboxylate ester groups as well as alcoholic hydroxyl groups, and an acid generator, wherein the action of the acid generated from the acid generator causes an intermolecular reaction between the carboxyl groups or carboxylate ester groups and the alcoholic hydroxyl groups within the resin component, thereby causing the resin component to change from an alkali-soluble state to an alkali-insoluble state.

[Patent Reference 1]

Japanese Examined Patent Application, Second Publication No. Hei 08-3635

[Patent Reference 2]

Japanese Unexamined Patent Application, First Publication No. 2000-206694

[Non-Patent Reference 1]

J. Photopolym. Sci. Tech., Vol. 10, No. 4, pages 579 to 584 (1997)

[Non-Patent Reference 2]

J. Photopolym. Sci. Tech., Vol. 11, No. 3, pages 507 to 512 (1998)

[Non-Patent Reference 3]

SPIE Advances in Resist Technology and Processing XIV, Vol. 3333, pages 417 to 424 (1998)

[Non-Patent Reference 4]

SPIE Advances in Resist Technology and Processing XIX, Vol. 4690, pages 94 to 100 (2002)

### DISCLOSURE OF INVENTION

However, with conventional negative resist compositions developed for use with ArF excimer lasers, the formed resist pattern tends to suffer from swelling caused by the alkali developing solution or the like.

Swelling of the resist pattern can cause deterioration in a variety of lithography characteristics including the resist pattern shape and the resolution, and as the resist pattern to be formed is miniaturized, for example in processes that aim to form resist patterns of no greater than 100 nm, swelling becomes an extremely significant problem.

The present invention takes the above circumstances into consideration, with an object of providing a negative resist composition and a method of forming a resist pattern that are capable of suppressing swelling of the resist pattern.

As a result of intensive investigation, the inventors of the present invention discovered that by using a copolymer containing 3 structural units with specific structures as the resin component of a negative resist composition, the object described above could be achieved, and they were therefore able to complete the present invention.

In other words, a first aspect of the present invention provides a negative resist composition including an alkali-soluble resin component (A), an acid generator component (B) that generates acid upon exposure, and a cross-linking agent component (C), wherein the alkali-soluble resin component (A) is a copolymer (A1) that includes a structural unit (a1) containing, within the main chain, an aliphatic cyclic group having a fluorinated hydroxyalkyl group, a structural unit (a2) derived from an acrylate ester which contains a hydroxyl group-containing chain-like or cyclic alkyl group and has a fluoroalkyl group or fluorine atom bonded to the α-position, and a structural unit (a3) derived from an acrylate ester which contains an aliphatic cyclic group having a fluorinated hydroxyalkyl group and has a fluoroalkyl group or fluorine atom bonded to the α-position.

A second aspect of the present invention is a method of forming a resist pattern, comprising the steps of applying a negative resist composition of the first aspect described above to a substrate, conducting a prebake, performing selective exposure, conducting PEB (post exposure baking), and performing alkali developing to form a resist pattern.

In the following description, the meanings of the terms used are as listed below.

A “structural unit” refers to a monomer unit that contributes to the formation of a polymer (resin).

A “structural unit derived from an acrylate ester” refers to a structural unit formed by cleavage of the ethylenic double bond of an acrylate ester.

The term “acrylate ester” is a general concept that includes not only the acrylate ester in which a hydrogen atom is bonded to the α-position carbon atom, but also structures in which a substituent group (an atom or group other than a hydrogen atom) is bonded to the α-position carbon atom. Examples of suitable substituent groups include a halogen atom such as a fluorine atom, an alkyl group or a haloalkyl group. In the present invention, structural units derived from acrylate esters in which a fluoroalkyl group or fluorine atom is bonded to the α-position are included as essential structural units.

In a “structural unit derived from an acrylate ester”, unless stated otherwise, the term “α-position” or “α-position carbon atom” refers to the carbon atom to which the carboxyl group is bonded.

Furthermore, unless stated otherwise, the term “alkyl group” includes straight-chain, branched-chain and cyclic monovalent saturated hydrocarbon groups.

Furthermore, the term “exposure” is not limited to irradiation with light, but describes a general concept that includes irradiation with any form of radiation, such as ultra violet radiation, X-rays or an electron beam.

According to the present invention, a negative resist composition and a method of forming a resist pattern are provided that are capable of suppressing swelling of the resist pattern.

### BEST MODE FOR CARRYING OUT THE INVENTION

As follows is a more detailed description of the present invention.

### [Negative Resist Composition]

A negative resist composition of the present invention includes an alkali-soluble resin component (A) (hereafter also referred to as the component (A)), an acid generator component (B) that generates acid upon exposure (hereafter also referred to as the component (B)), and a cross-linking agent component (C) (hereafter also referred to as the component (C)).

In this negative resist composition, when acid is generated from the component (B) by exposure (irradiation) during formation of a resist pattern, the action of this acid causes cross-linking between the component (A) and the component (C), causing the composition to become insoluble in alkali.

In the present invention, the component (A) is a copolymer (A1) that includes a structural unit (a1) containing, within the main chain, an aliphatic cyclic group having a fluorinated hydroxyalkyl group, a structural unit (a2) derived from an acrylate ester which contains a hydroxyl group-containing chain-like or cyclic alkyl group and has a fluoroalkyl group or fluorine atom bonded to the α-position, and a structural unit (a3) derived from an acrylate ester which contains an aliphatic cyclic group having a fluorinated hydroxyalkyl group and has a fluoroalkyl group or fluorine atom bonded to the α-position

Structural Unit (a1)

In the structural unit (a1), the “aliphatic cyclic group having a fluorinated hydroxyalkyl group” refers to a group in which a fluorinated hydroxyalkyl group is bonded to a carbon atom that constitutes part of an aliphatic cyclic group.

Furthermore, the description of “containing the aliphatic cyclic group within the main chain” means that at least one, and preferably two or more carbon atoms within the ring structure of the alicyclic group constitute part of the main chain of the copolymer (A1).

In the present invention, by including a copolymer (A1) that contains a structural unit (a1) with this structure, pattern swelling can be suppressed, while solubility within the alkali developing solution is retained. Furthermore, because the copolymer includes an alicyclic group of high carbon density within the main chain, improvements in the etching resistance can also be expected.

A “fluorinated hydroxyalkyl group” refers to a hydroxyalkyl group, in which a portion of the hydrogen atoms of an alkyl group have been substituted with hydroxyl groups, wherein a portion of, or all of, the remaining hydrogen atoms within the hydroxyalkyl group have been substituted with fluorine atoms. In a fluorinated hydroxyalkyl group, the fluorination increases the ease with which the hydrogen atom of the hydroxyl group is released.

In the fluorinated hydroxyalkyl group, the alkyl group is either a straight-chain or branched-chain alkyl group. Although there are no particular restrictions on the number of carbon atoms within the alkyl group, the number of carbon atoms is preferably from 1 to 20, even more preferably from 4 to 16, and is most preferably from 4 to 12. There are no particular restrictions on the number of hydroxyl groups, although a single hydroxyl group is typical.

Of the various possibilities, groups in which a fluoroalkyl group and/or a fluorine atom is bonded to the carbon atom to which the hydroxyl group is bonded (which refers to the α-position carbon atom of the hydroxyalkyl group) are preferred as the fluorinated hydroxyalkyl group. Furthermore, the fluoroalkyl group bonded to the α-position is preferably a group in which all of the hydrogen atoms of the alkyl group have been substituted with fluorine atoms. Furthermore, as the alkyl group of this fluoroalkyl group, a straight-chain or branched-chain alkyl group of 1 to 5 carbon atoms is preferred.

The term “aliphatic” in the expression “aliphatic cyclic group having a fluorinated hydroxyalkyl group” is a relative concept used in relation to the term “aromatic”, and defines a group or compound or the like that contains no aromaticity.

The aliphatic cyclic group may be either monocyclic or polycyclic. The term “monocyclic aliphatic cyclic group” describes a monocyclic group that contains no aromaticity, whereas the term “polycyclic aliphatic cyclic group” describes a polycyclic group that contains no aromaticity. In the structural unit (a1), the aliphatic cyclic group is preferably a polycyclic group, as such groups provide superior etching resistance and the like.

The aliphatic cyclic group includes both hydrocarbon groups formed solely from carbon and hydrogen (alicyclic groups), and heterocyclic groups in which a portion of the carbon atoms that constitute the ring structure of the alicyclic group have been substituted with a hetero atom such as an oxygen atom, nitrogen atom, or sulfur atom. These aliphatic cyclic groups may contain substituent groups, and examples of suitable substituent groups include alkyl groups of 1 to 5 carbon atoms. The expression “contain substituent groups” means that either a portion of, or all of, the hydrogen atoms bonded to the carbon atoms that constitute the ring structure of the aliphatic cyclic group have been substituted with a substituent group (an atom or group other than a hydrogen atom). In the present invention, an alicyclic group is preferred as the aliphatic cyclic group.

The aliphatic cyclic group may be either saturated or unsaturated, although a saturated group is preferred, as such groups exhibit superior transparency to ArF excimer lasers and the like, and also exhibit excellent resolution and depth of focus (DOF).

The number of carbon atoms within the aliphatic cyclic group is preferably within a range from 5 to 15.

Specific examples of the aliphatic cyclic group include the groups described below.

Examples of suitable monocyclic groups include groups in which two or more hydrogen atoms have been removed from a cycloalkane. Specific examples include groups in which two or two hydrogen atoms have been removed from cyclopentane or cyclohexane, and groups in which two or more hydrogen atoms have been removed from cyclohexane are particularly preferred.

Examples of suitable polycyclic groups include groups in which two or more hydrogen atoms have been removed from a bicycloalkane, tricycloalkane or tetracycloalkane or the like. Specific examples include groups in which two or more hydrogen atoms have been removed from a polycycloalkane such as adamantane, norbornane, isobornane, tricyclodecane or tetracyclododecane.

These types of aliphatic cyclic groups can be selected appropriately from the multitude of groups proposed for the resins of photoresist compositions used within ArF excimer laser processes.

Of the various possibilities, groups in which two or more hydrogen atoms have been removed from cyclohexane, adamantane, norbornane or tetracyclododecane are readily available industrially, and are consequently preferred.

Of the alicyclic groups exemplified above, groups such as those shown in a structural unit (a1-1) below, in which three hydrogen atoms have been removed from norbornane or tetracyclododecane, are preferred, and groups in which three hydrogen atoms have been removed from norbornane are particularly desirable.

Specific examples of preferred forms of the structural unit (a1) include structural units (a1-1) represented by the general formula (a1-1) shown below. Including the structural unit (a1-1) enables effective inhibition of pattern swelling. Furthermore, the resolution is also excellent.

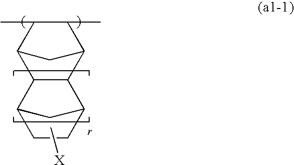

[wherein, X represents a fluorinated hydroxyalkyl group, and r is either 0 or 1]

In the formula (a1-1), r is either 0 or 1, and in terms of industrial availability, is preferably 0.

X represents a fluorinated hydroxyalkyl group. Structural units in which X is a group represented by a general formula (a1-1-1) shown below provide particularly superior resist pattern shape as well as reduced levels of line edge roughness (LER), and are consequently preferred.

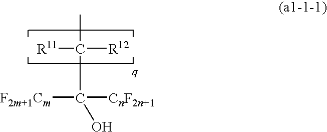

[wherein, R¹¹ and R¹² each represent, independently, a hydrogen atom or a lower alkyl group, m and n each represent, independently, an integer from 1 to 5, and q also represents an integer from 1 to 5]

In the formula (a1-1-1), R¹¹ and R¹² each represent, independently, a hydrogen atom or a lower alkyl group. As the lower alkyl group, a lower alkyl group of 1 to 5 carbon atoms is preferred, and specific examples include a methyl group, ethyl group, propyl group, isopropyl group, n-butyl group, isobutyl group, tert-butyl group, pentyl group, isopentyl group or neopentyl group, and a methyl group is particularly desirable.

q represents an integer from 1 to 5, and preferably an integer from 1 to 3, and is most preferably 1.

m and n each represent, independently, an integer from 1 to 5, and preferably an integer from 1 to 3, and those cases in which both m and n are 1 are preferred in terms of ease of synthesis and the effects achieved.

The structural unit (a1) may use either a single structural unit, or a mixture of two or more different units.

The proportion of the structural unit (a1) within the copolymer (A1), relative to the combined total of all the structural units that constitute the copolymer (A1), is preferably within a range from 10 to 70 mol %, even more preferably from 10 to 60 mol %, and is most preferably from 15 to 50 mol %. Ensuring that this proportion is at least as large as the lower limit of the above range enables the effects achieved by including the structural unit (a1) to be readily obtained, whereas ensuring that the proportion is no greater than the upper limit enables a favorable balance to be achieved with the other structural units.

Structural Unit (a2)

The structural unit (a2) is a structural unit derived from an acrylate ester which contains a hydroxyl group-containing chain-like or cyclic alkyl group and has a fluoroalkyl group or fluorine atom bonded to the α-position.

In the present invention, including the structural unit (a2) improves the swelling suppression effect.

Furthermore, the hydroxyl group (alcoholic hydroxyl group) of the structural unit (a2) exhibits excellent cross-linkability with the component (C), meaning that by including the structural unit (a2) within the component (A), the difference in the solubility within the alkali developing solution (the contrast) between the exposed portions and the unexposed portions can be increased, enabling the composition to function effectively as a negative resist.

Of the various possibilities, if the structural unit (a2) includes a structural unit derived from an acrylate ester which contains a hydroxyl group-containing cyclic alkyl group and has a fluoroalkyl group or fluorine atom bonded to the α-position (hereafter also referred to as simply a “structural unit containing a hydroxyl group-containing cyclic alkyl group”), then the pattern swelling suppression effect is particularly large. Furthermore, the resolution is also high, and the exposure margin improves.

In addition, the contrast and etching resistance are also excellent.

Furthermore, if the structural unit (a2) includes a structural unit derived from an acrylate ester containing a hydroxyl group-containing chain-like alkyl group and having a fluoroalkyl group or fluorine atom bonded to the α-position (hereafter also referred to as simply a “structural unit containing a hydroxyl group-containing chain-like alkyl group”), then the hydrophilicity of the entire component (A) increases, improving the resolution. Furthermore, the controllability of the cross-linking reaction that occurs during pattern formation is favorable, enabling improvements in both the pattern shape and the resolution. In addition, the film density tends to increase which enables thickness loss during etching to be suppressed, and the heat resistance also tends to improve.

In the structural unit (a2), the fluoroalkyl group or fluorine atom bonded to the α-position of the acrylate ester is preferably a fluoroalkyl group.

The fluoroalkyl group bonded to the α-position is preferably a group in which all of the hydrogen atoms of the alkyl group have been substituted with fluorine atoms. Furthermore, the alkyl group of the fluoroalkyl group is preferably a straight-chain or branched-chain alkyl group of 1 to 5 carbon atoms, and a trifluoromethyl group (—CF₃) is particularly desirable.

### “Structural Unit Containing a Hydroxyl Group-Containing Cyclic Alkyl Group”

Examples of the structural unit containing a hydroxyl group-containing cyclic alkyl group include structural units in which the hydroxyl group-containing cyclic alkyl group is bonded to the ester group [—C(O)O—] of the acrylate ester. Here, the term “hydroxyl group-containing cyclic alkyl group” refers to a cyclic alkyl group to which a hydroxyl group is bonded.

The number of bonded hydroxyl groups is preferably within a range from 1 to 35 and is most preferably 1.

The cyclic alkyl group may be either monocyclic or polycyclic, but is preferably a polycyclic group. Furthermore, the number of carbon atoms within the cyclic alkyl group is preferably within a range from 5 to 15.

Specific examples of the cyclic alkyl group are described below.

Examples of suitable monocyclic cyclic alkyl groups include groups in which 1 to 4 hydrogen atoms have been removed from a cycloalkane. Specific examples of such monocyclic cyclic alkyl groups include groups in which 1 to 4 hydrogen atoms have been removed from cyclopentane or cyclohexane, and of these, a cyclohexyl group is preferred.

Examples of suitable polycyclic cyclic alkyl groups include groups in which 1 to 4 hydrogen atoms have been removed from a bicycloalkane, tricycloalkane, or tetracycloalkane or the like. Specific examples include groups in which 1 to 4 hydrogen atoms have been removed from a polycycloalkane such as adamantane, norbornane, isobornane, tricyclodecane, or tetracyclododecane.

These types of cyclic alkyl groups can be selected appropriately from the multitude of groups proposed for forming acid-dissociable, dissolution-inhibiting groups for use within resins for photoresist compositions used within ArF excimer laser processes. Of the various possibilities, cyclohexyl groups, adamantyl groups, norbornyl groups, and tetracyclododecanyl groups are readily available industrially, and are consequently preferred.

Of the various monocyclic groups and polycyclic groups exemplified above, a cyclohexyl group or adamantyl group is preferred, and an adamantyl group is particularly desirable.

Specific examples of structural units containing a hydroxyl group-containing cyclic alkyl group include structural units (a2-1) represented by a general formula (a2-1) shown below.

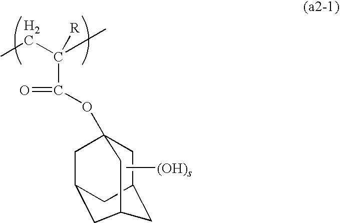

[wherein, R represents a fluoroalkyl group or a fluorine atom, and s represents an integer from 1 to 3]

In the formula (a2-1), R represents a fluoroalkyl group or a fluorine atom, and is preferably a fluoroalkyl group of 1 to 5 carbon atoms, and even more preferably a fluoroalkyl group of 1 to 4 carbon atoms. A fluoroalkyl group is a group in which a portion of, or all of, the hydrogen atoms have been substituted with fluorine atoms, and groups in which all of the hydrogen atoms have been substituted with fluorine atoms are preferred. R is most preferably a trifluoromethyl group.

s represents an integer from 1 to 3, and is most preferably 1.

Although there are no particular restrictions on the bonding position of the hydroxyl group, units in which the hydroxyl group is bonded to position 3 of the adamantyl group are preferred.

### “Structural Unit Containing a Hydroxyl Group-Containing Chain-Like Alkyl Group”

Examples of the structural unit containing a hydroxyl group-containing chain-like alkyl group include structural units in which a hydroxyalkyl group is bonded to the ester group [—C(O)O—] of the acrylate ester.

As the structural unit containing a hydroxyl group-containing chain-like alkyl group, a structural unit (a2-2) represented by a general formula (a2-2) shown below is particularly preferred.

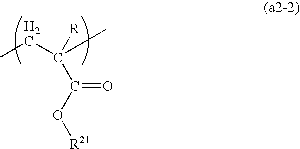

[wherein, R represents a fluoroalkyl group or a fluorine atom, and R represents a hydroxyalkyl group]

In the formula (a2-2), R has the same meaning as R within the above general formula (a2-1).

The hydroxyalkyl group represented by R²¹ is preferably a lower hydroxyalkyl group of no more than 10 carbon atoms, even more preferably a lower hydroxyalkyl group of 2 to 8 carbon atoms, and is most preferably a straight-chain lower hydroxyalkyl group of 2 to 4 carbon atoms.

There are no particular restrictions on the number of hydroxyl groups within the hydroxyalkyl group or the bonding positions of those groups, although one hydroxyl group is typical, and the hydroxyl group is preferably bonded to the terminal of the alkyl group.

The structural unit (a2) may use either a single structural unit, or a mixture of two or more different units.

In the present invention, those cases in which the structural unit (a2) includes at least a structural unit containing a hydroxyl group-containing cyclic alkyl group are preferred, and those cases in which the structural unit (a2) includes both a structural unit containing a hydroxyl group-containing cyclic alkyl group and a structural unit containing a hydroxyl group-containing chain-like alkyl group are even more desirable.

Those cases in which the structural unit (a2) includes both a structural unit (a2-1) and a structural unit (a2-2) yield particularly superior effects for the present invention and are consequently preferred. In these cases, the ratio (molar ratio) between the structural unit (a-1) and the structural unit (a2-2) within the copolymer (A1), namely the ratio structural unit (a2-1): structural unit (a2-2) is preferably within a range from 9:1 to 1:9, is even more preferably from 8:2 to 2:8, and is most preferably from 6:4 to 7:3.

By including a favorable balance between the structural unit (a2-1) and the structural unit (a2-2), a suitable level of contrast is achieved, and the resolution improves. Furthermore, the etching resistance also improves. In addition, a favorable exposure margin is also obtained.

The proportion of the structural unit (a2) within the copolymer (A1), relative to the combined total of all the structural units that constitute the copolymer (A1), is preferably within a range from 10 to 80 mol %, even more preferably from 15 to 60 mol %, and is most preferably from 20 to 55 mol % Ensuring that this proportion is at least as large as the lower limit of the above range enables the effects achieved by including the structural unit (a2) to be readily obtained, whereas ensuring that the proportion is no greater than the upper limit enables a favorable balance to be achieved with the other structural units.

Structural Unit (a3)

The structural unit (a3) is a structural unit derived from an acrylate ester which contains an aliphatic cyclic group having a fluorinated hydroxyalkyl group and has a fluoroalkyl group or fluorine atom bonded to the α-position. In the present invention, by using a copolymer (A1) containing a structural unit (a3) with this type of structure, pattern swelling can be suppressed, while solubility within the alkali developing solution is retained.

In the structural unit (a3), examples of the aliphatic cyclic group having a fluorinated hydroxyalkyl group are the same as the aliphatic cyclic groups described above in relation to the structural unit (a1).

The structural unit (a3) is a structural unit derived from acrylic acid, and is preferably a unit in which the aforementioned aliphatic cyclic group is bonded to the ester group [—C(O)O—] of an acrylate ester (namely, a structure in which the hydrogen atom of the carboxyl group is substituted with the aliphatic cyclic group).

Specific examples of preferred forms of the structural unit (a3) include the units represented by a general formula (a3-1) shown below.

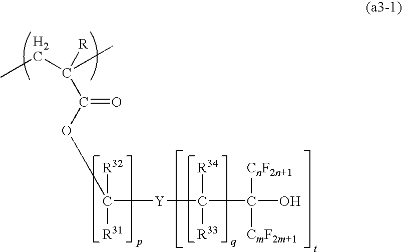

[wherein, R represents a fluoroalkyl group or a fluorine atom, R³¹ to R³⁴ each represent, independently, a hydrogen atom or a lower alkyl group, p and q each represent, independently, either 0 or an integer from 1 to 3, m and n each represent, independently, an integer from 1 to 5, t represents an integer from 1 to 3, and Y represents an aliphatic cyclic group]

In the formula (a3-1), R has the same meaning as R within the above general formula (a2-1).

R³¹ to R³⁴ each represent, independently, a hydrogen atom or a lower alkyl group, and examples of suitable lower alkyl groups include the same lower alkyl groups as those described in relation to the groups R¹¹ and R¹² within the above formula (a1-1-1).

p and q each represent, independently, either 0 or an integer from 1 to 3, preferably either 0 or 1, and are most preferably 0.

m and n have the same meaning as m and n within the above formula (a1-1-1).

t is an integer from 1 to 3, is preferably either 1 or 2, and is most preferably 2.

Y represents an aliphatic cyclic group with a valency of (t+1). Here the expression “aliphatic cyclic group with a valency of (t+1)” describes a group in which (t+1) hydrogen atoms have been removed from carbon atoms that constitute the ring skeleton of the aliphatic ring.

The aliphatic cyclic group of Y may be either monocyclic or polycyclic, although in terms of achieving superior effects for the present invention, is preferably a monocyclic group.

The Y group preferably contains from 3 to 20 carbon atoms, and even more preferably from 4 to 15 carbon atoms. Specific examples of Y include groups in which (t+1) hydrogen atoms have been removed from a polycycloalkane such as a monocycloalkane, bicycloalkane, tricycloalkane, or tetracycloalkane. Specific examples include groups in which (t+1) hydrogen atoms have been removed from cyclopentane, cyclohexane, adamantane, norbornane, isobornane, tricyclodecane or tetracyclododecane. In the present invention, Y is most preferably a group in which (t+1) hydrogen atoms have been removed from cyclohexane.

The structural unit (a3) may use either a single structural unit, or a mixture of two or more different units.

The proportion of the structural unit (a3) within the copolymer (A1), relative to the combined total of all the structural units that constitute the copolymer (A1), is preferably within a range from 5 to 50 mol %, even more preferably from 10 to 40 mol %, and is most preferably from 10 to 30 mol %. Ensuring that this proportion is at least as large as the lower limit of the above range enables the effects achieved by including the structural unit (a3) to be readily obtained, whereas ensuring that the proportion is no greater than the upper limit enables a favorable balance to be achieved with the other structural units.

The copolymer (A1) may include other copolymerizable structural units besides the structural units (a1) through (a3), but in order to achieve superior effects for the present invention, resins in which the structural units (a1) to (a3) are the primary components are preferred. Here, the term “primary components” means that the combined total of these structural units accounts for at least 50 mol %, preferably at least 70 mol %, and even more preferably 80 mol % or greater of all the structural units. The most preferred resins are copolymers formed solely from the structural units (a1), (a2) and (a3).

In those cases where the copolymer (A1) is a copolymer formed solely from the structural units (a1), (a2) and (a3), the respective proportions of each structural unit within the copolymer (A1), relative to the combined total of all the structural units that constitute the copolymer (A1), are from 10 to 70 mol % for the structural unit (a1), from 10 to 80 mol % for the structural unit (a2), and from 5 to 50 mol % for the structural unit (a3).

In the present invention, copolymers (A1) that contain the structural unit (a1), the structural unit (a2-1), the structural unit (a2-2), and the structural unit (a3) are preferred as they yield particularly superior effects for the present invention, and copolymers (A1) formed solely from the structural unit (a1), the structural unit (a2-1), the structural unit (a2-2) and the structural unit (a3) are even more desirable.

In those cases where the copolymer (A1) is formed solely from the structural units (a1), (a2-1), (a2-2) and (a3), the respective proportions of the structural unit (a1), the structural unit (a2-1), the structural unit (a2-2) and the structural unit (a3) within the copolymer (A1) preferably satisfy the numerical ranges described below. Namely, the proportion of the structural unit (a1) is preferably within a range from 20 to 70 mol %, and is even more preferably from 25 to 45 mol %. The proportion of the structural unit (a2-1) is preferably within a range from 10 to 50 mol %, and is even more preferably from 15 to 40 mol %. The proportion of the structural unit (a2-2) is preferably within a range from 10 to 50 mol %, and is even more preferably from 15 to 35 mol %. The proportion of the structural unit (a3) is preferably within a range from 10 to 40 mol %, and is even more preferably from 15 to 30 mol %. If the above ranges are satisfied, then the effect of the invention in suppressing swelling is particularly superior.

Furthermore, in the negative resist composition of the present invention, the component (A) may also include, in addition to the structural units (a1) to (a3) described above, any of the structural units typically used within the components (A) used in conventional chemically amplified resist compositions.

Weight Average Molecular Weight

The weight average molecular weight (Mw: the polystyrene equivalent weight average molecular weight determined using gel permeation chromatography (GPC)) of the copolymer (A1) is preferably within a range from 2,000 to 30,000, and is even more preferably from 2,000 to 10,000. Ensuring a molecular weight within this range is preferred in terms of ensuring a favorable swelling suppression effect and suppressing the occurrence of the resulting microbridges. Furthermore, a molecular weight within the above range is also preferred in terms of achieving a high level of resolution. Within this range, lower molecular weights tend to result in more favorable properties. Furthermore, the polydispersity (Mw/Mn) is typically within a range from 1.0 to 5.0, and is preferably from 1.0 to 2.5.

The copolymer (A1) can be obtained, for example, by a conventional radical polymerization of the monomers that yield each of the structural units.

The component (A) may use either a single copolymer (A1), or a mixture of two or more different copolymers.

The quantity of the component (A) within the negative resist composition can be adjusted appropriately in accordance with the thickness of the resist film that is to be formed.

The component (B) can use any of the known acid generators used in conventional chemically amplified resist compositions without any particular restrictions. Examples of the types of acid generators that have been used are numerous, and include onium salt-based acid generators such as iodonium salts and sulfonium salts, oxime sulfonate-based acid generators, diazomethane-based acid generators such as bisalkyl or bisaryl sulfonyl diazomethanes, and poly(bis-sulfonyl)diazomethanes, nitrobenzyl sulfonate-based acid generators, iminosulfonate-based acid generators, and disulfone-based acid generators.

Examples of suitable onium salt-based acid generators include compounds represented by general formulas (b-1) and (b-2) shown below.

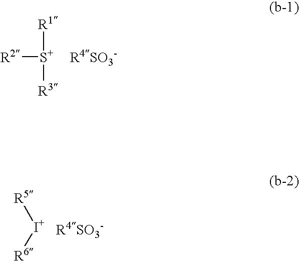

[wherein, R^{1″} to R^{3″}, and R^{5″} to R^{6″} each represent, independently, an aryl group or an alkyl group; and R^{4″} represents a straight-chain, branched or cyclic alkyl group or fluoroalkyl group; provided that at least one of R^{1″} to R^{3″} represents an aryl group, and at least one of R^{5″} to R^{6″} represents an aryl group]

In the formula (b-1), R^{1″} to R^{3″} each represent, independently, an aryl group or an alkyl group. Of the groups R^{1″} to R^{3″}, at least one group represents an aryl group. Compounds in which at least two of R^{1″} to R^{3″} represent aryl groups are preferred, and compounds in which all of R^{1″} to R^{3″} are aryl groups are the most preferred.

There are no particular restrictions on the aryl groups of R^{1″} to R^{3″}, and suitable examples include aryl groups of 6 to 20 carbon atoms, in which either a portion of, or all of, the hydrogen atoms of these aryl groups may be either substituted, or not substituted, with alkyl groups, alkoxy groups, or halogen atoms and the like. In terms of enabling low-cost synthesis, aryl groups of 6 to 10 carbon atoms are preferred. Specific examples of suitable groups include a phenyl group and a naphthyl group.

Alkyl groups that may be used for substitution of the hydrogen atoms of the above aryl groups are preferably alkyl groups of 1 to 5 carbon atoms, and a methyl group, ethyl group, propyl group, n-butyl group or tert-butyl group is the most desirable.

Alkoxy groups that may be used for substitution of the hydrogen atoms of the above aryl groups are preferably alkoxy groups of 1 to 5 carbon atoms, and a methoxy group or ethoxy group is the most desirable. Halogen atoms that may be used for substitution of the hydrogen atoms of the above aryl groups are preferably fluorine atoms.

There are no particular restrictions on the alkyl groups of R^{1″} to R^{3″}, and suitable examples include straight-chain, branched, or cyclic alkyl groups of 1 to 10 carbon atoms. From the viewpoint of achieving excellent resolution, alkyl groups of 1 to 5 carbon atoms are preferred. Specific examples include a methyl group, ethyl group, n-propyl group, isopropyl group, n-butyl group, isobutyl group, n-pentyl group, cyclopentyl group, hexyl group, cyclohexyl group, nonyl group, and decanyl group, although in terms of achieving superior resolution and enabling low-cost synthesis, a methyl group is the most desirable.

Of the above possibilities, compounds in which R^{1″} to R^{3″} are all phenyl groups are the most preferred.

The group R^{4″} represents a straight-chain, branched or cyclic alkyl group or fluoroalkyl group.

As the straight-chain alkyl group, groups of 1 to 10 carbon atoms are preferred, groups of 1 to 8 carbon atoms are even more preferred, and groups of 1 to 4 carbon atoms are the most desirable. Suitable cyclic alkyl groups include the same groups as those listed above in relation to the group R^{1″}, and cyclic groups of 4 to 15 carbon atoms are preferred, groups of 4 to 10 carbon atoms are even more preferred, and groups of 6 to 10 carbon atoms are the most desirable.

As the above fluoroalkyl group, groups of 1 to 10 carbon atoms are preferred, groups of 1 to 8 carbon atoms are even more preferred, and groups of 1 to 4 carbon atoms are the most desirable. Furthermore, the fluorination ratio of the fluoroalkyl group (namely, the fluorine atom proportion within the alkyl group) is preferably within a range from 10 to 100%, and even more preferably from 50 to 100%, and groups in which all of the hydrogen atoms have been substituted with fluorine atoms yield the strongest acids, and are consequently the most desirable.

The group R^{4″} is most preferably a straight-chain or cyclic alkyl group, or a fluoroalkyl group.

In the formula (b-2), R^{5″} to R^{6″} each represent, independently, an aryl group or an alkyl group. At least one of R^{5″} to R^{6″} represents an aryl group. Compounds in which all of R^{5″} to R^{6″} are aryl groups are the most preferred.

Suitable examples of the aryl groups of the groups R^{5″} to R^{6″} include the same aryl groups as those described above for the groups R^{1″} to R^{3″}.

Suitable examples of the alkyl groups of the groups R^{5″} to R^{6″} include the same alkyl groups as those described above for the groups R^{1″} to R^{3″}.

Of the above possibilities, compounds in which R^{5″} to R^{6″} are all phenyl groups are the most preferred.

Suitable examples of the group R^{4″} in the formula (b-2) include the same groups as those described for the group R^{4″} in the aforementioned formula (b-1).

Specific examples of suitable onium salt-based acid generators include diphenyliodonium trifluoromethanesulfonate or nonafluorobutanesulfonate, bis(4-tert-butylphenyl)iodonium trifluoromethanesulfonate or nonafluorobutanesulfonate, triphenylsulfonium trifluoromethanesulfonate, heptafluoropropanesulfonate or nonafluorobutanesulfonate, tri(4-methylphenyl)sulfonium trifluoromethanesulfonate, heptafluoropropanesulfonate or nonafluorobutanesulfonate, dimethyl(4-hydroxynaphthyl)sulfonium trifluoromethanesulfonate, heptafluoropropanesulfonate or nonafluorobutanesulfonate, monophenyldimethylsulfonium trifluoromethanesulfonate, heptafluoropropanesulfonate or nonafluorobutanesulfonate, diphenylmonomethylsulfonium trifluoromethanesulfonate, heptafluoropropanesulfonate or nonafluorobutanesulfonate, (4-methylphenyl)diphenylsulfonium trifluoromethanesulfonate, heptafluoropropanesulfonate or nonafluorobutanesulfonate, (4-methoxyphenyl)diphenylsulfonium trifluoromethanesulfonate, heptafluoropropanesulfonate or nonafluorobutanesulfonate, tri(4-tert-butyl)phenylsulfonium trifluoromethanesulfonate, heptafluoropropanesulfonate or nonafluorobutanesulfonate, and diphenyl(1-(4-methoxy)naphthyl)sulfonium trifluoromethanesulfonate, heptafluoropropanesulfonate or nonafluorobutanesulfonate. Furthermore, onium salts in which the anion portion of the above onium salts have been substituted with methanesulfonate, n-propanesulfonate, n-butanesulfonate, or n-octanesulfonate can also be used.

Compounds in which the anion portion within the above general formulas (b-1) and (b-2) has been substituted with an anion portion represented by a general formula (b-3) or (b-4) shown below (and in which the cation portion is the same as that shown in (b-1) or (b-2)) can also be used.

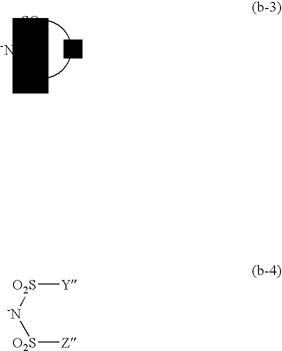

[wherein, X″ represents an alkylene group of 2 to 6 carbon atoms in which at least one hydrogen atom has been substituted with a fluorine atom; Y″ and Z″ each represent, independently, an alkyl group of 1 to 10 carbon atoms in which at least one hydrogen atom has been substituted with a fluorine atom]

The group X″ is a straight-chain or branched alkylene group in which at least one hydrogen atom has been substituted with a fluorine atom, and the number of carbon atoms within the alkylene group is typically within a range from 2 to 6, preferably from 3 to 5, and is most preferably 3.

Y″ and Z″ each represent, independently, a straight-chain or branched alkyl group in which at least one hydrogen atom has been substituted with a fluorine atom, and the number of carbon atoms within the alkyl group is typically within a range from 1 to 10, preferably from 1 to 7, and is most preferably from 1 to 3.

Within the above ranges for the numbers of carbon atoms, lower numbers of carbon atoms within the alkylene group X″ or the alkyl groups Y″ and Z″ result in better solubility within the resist solvent, and are consequently preferred.

Furthermore, in the alkylene group X″ or the alkyl groups Y″ and Z″, the larger the number of hydrogen atoms that have been substituted with fluorine atoms, the stronger the acid becomes, and the transparency relative to high energy light beams of 200 nm or less or electron beams also improves favorably. The fluorine atom proportion within the alkylene group or alkyl groups, namely the fluorination ratio, is preferably within a range from 70 to 100%, and even more preferably from 90 to 100%, and perfluoroalkylene or perfluoroalkyl groups in which all of the hydrogen atoms have been substituted with fluorine atoms are the most desirable.

In the present invention, the term “oxime sulfonate-based acid generator” describes a compound that contains at least one group represented by a general formula (B-1) shown below, and generates acid upon irradiation. These types of oxime sulfonate-based acid generators are widely used within chemically amplified resist compositions, and any of these conventional compounds can be used.

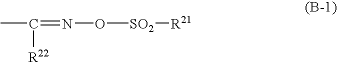

(In the formula (B-1), R²¹ and R²² each represent, independently, an organic group.)

In the present invention, the above organic groups preferably include carbon atoms, and may also include atoms other than carbon atoms (such as hydrogen atoms, oxygen atoms, nitrogen atoms, sulfur atoms, and halogen atoms (such as fluorine atoms or chlorine atoms)).

The organic group of R²¹ is preferably a straight-chain, branched or cyclic alkyl group or aryl group. These alkyl groups or aryl groups may also include a substituent group. There are no particular restrictions on such substituent groups, and suitable examples include a fluorine atom or a straight-chain, branched or cyclic alkyl group of 1 to 6 carbon atoms. Here, the expression “include a substituent group” means that either a portion of, or all of, the hydrogen atoms of the alkyl group or aryl group may be substituted with substituent groups.

The alkyl group preferably contains from 1 to 20 carbon atoms, even more preferably from 1 to 10 carbon atoms, even more preferably from 1 to 8 carbon atoms, and most preferably from 1 to 6 carbon atoms. Furthermore, alkyl groups that are partially or completely halogenated (hereafter also referred to as haloalkyl groups) are preferred. A partially halogenated alkyl group is an alkyl group in which a portion of the hydrogen atoms have been substituted with halogen atoms, whereas a completely halogenated alkyl group is an alkyl group in which all of the hydrogen atoms have been substituted with halogen atoms. Examples of the halogen atoms include fluorine atoms, chlorine atoms, bromine atoms or iodine atoms, although fluorine atoms are particularly desirable. In other words, the haloalkyl group is preferably a fluoroalkyl group.

The aryl group preferably contains from 4 to 20 carbon atoms, even more preferably from 4 to 10 carbon atoms, and most preferably from 6 to 10 carbon atoms. Aryl groups that are partially or completely halogenated are preferred. A partially halogenated aryl group is an aryl group in which a portion of the hydrogen atoms have been substituted with halogen atoms, whereas a completely halogenated aryl group is an aryl group in which all of the hydrogen atoms have been substituted with halogen atoms.

As the group R²¹, an alkyl group of 1 to 4 carbon atoms containing no substituent groups, or a fluoroalkyl group of 1 to 4 carbon atoms is the most desirable.

The organic group of R²² is preferably a straight-chain, branched or cyclic alkyl group or aryl group, or a cyano group. Examples of suitable alkyl groups and aryl groups for R²² include the same alkyl groups and aryl groups described above in relation to R²¹.

As the group R²², a cyano group, an alkyl group of 1 to 8 carbon atoms containing no substituent groups, or a fluoroalkyl group of 1 to 8 carbon atoms is the most desirable.

Particularly preferred oxime sulfonate-based acid generators include the compounds represented by the general formulas (B-2) and (B-3) shown below.

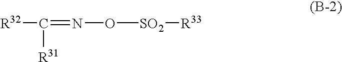

[In the formula (B-2), R³¹ represents a cyano group, an alkyl group containing no substituent groups, or a haloalkyl group. R³² represents an aryl group. R³³ represents an alkyl group containing no substituent groups, or a haloalkyl group.]

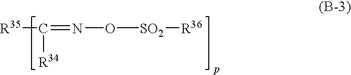

[In the formula (B-3), R³⁴ represents a cyano group, an alkyl group containing no substituent groups, or a haloalkyl group. R³⁵ represents a bivalent or trivalent aromatic hydrocarbon group. R³⁶ represents an alkyl group containing no substituent groups, or a haloalkyl group. p is either 2 or 3.]

In the above general formula (B-2), the alkyl group containing no substituent groups or haloalkyl group represented by R³¹ preferably contains from 1 to 10 carbon atoms, even more preferably from 1 to 8 carbon atoms, and most preferably from 1 to 6 carbon atoms.

The group R³¹ is preferably a haloalkyl group, and even more preferably a fluoroalkyl group.

In the fluoroalkyl group of R³¹, at least 50% of the hydrogen atoms of the alkyl group are preferably fluorinated, and this ratio is even more preferably 70% or higher, and is most preferably 90% or higher.

The aryl group represented by R³² is preferably a group in which one hydrogen atom has been removed from an aromatic hydrocarbon ring, such as a phenyl group, biphenyl group, fluorenyl group, naphthyl group, anthracyl group or phenanthryl group, or a heteroaryl group in which a portion of the carbon atoms that constitute the ring structure within the above groups have been substituted with a hetero atom such as an oxygen atom, sulfur atom or nitrogen atom. Of these possibilities, a fluorenyl group is particularly preferred.

The aryl group of R³² may include a substituent group such as an alkyl group, haloalkyl group or alkoxy group of 1 to 10 carbon atoms. The alkyl group or haloalkyl group substituent groups preferably contain from 1 to 8 carbon atoms, and even more preferably 1 to 4 carbon atoms. Furthermore, the haloalkyl group is preferably a fluoroalkyl group.

The alkyl group containing no substituent groups or haloalkyl group represented by R³³ preferably contains from 1 to 10 carbon atoms, even more preferably from 1 to 8 carbon atoms, and most preferably from 1 to 6 carbon atoms.

The group R³³ is preferably a haloalkyl group, even more preferably a fluoroalkyl group, and is most preferably a partially fluorinated alkyl group.

In the fluoroalkyl group of R³³, at least 50% of the hydrogen atoms of the alkyl group are preferably fluorinated, and groups in which 70% or more, and even more preferably 90% or more, of the hydrogen atoms are fluorinated are particularly desirable as they increase the strength of the acid that is generated. Completely fluorinated alkyl groups in which 100% of the hydrogen atom have been substituted with fluorine atoms are the most desirable.

In the above general formula (B-3), examples of the alkyl group containing no substituent groups or haloalkyl group represented by R³⁴ include the same alkyl groups containing no substituent groups and haloalkyl groups described above for the group R³¹.

Examples of the bivalent or trivalent aromatic hydrocarbon group represented by R³⁵ include groups in which a further one or two hydrogen atoms respectively are removed from an aryl group of the aforementioned group R³².

Examples of the alkyl group containing no substituent groups or haloalkyl group represented by R³⁶ include the same alkyl groups containing no substituent groups and haloalkyl groups described above for the group R³³.

p is preferably 2.

Specific examples of suitable oxime sulfonate-based acid generators include α-(p-toluenesulfonyloxyimino)-benzyl cyanide, α-(p-chlorobenzenesulfonyloxyimino)-benzyl cyanide, α-(4-nitrobenzenesulfonyloxyimino)-benzyl cyanide, α-(4-nitro-2-trifluoromethylbenzenesulfonyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(benzenesulfonyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)-benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-(propylsulfonyloxyimino)-propyl acetonitrile, α-(cyclohexylsulfonyloxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α-(ethylsulfonyloxyimino)-1-cyclopentenyl acetonitrile, α-(isopropylsulfonyloxyimino)-1-cyclopentenyl acetonitrile, α-(n-butylsulfonyloxyimino)-1-cyclopentenyl acetonitrile, α-(ethylsulfonyloxyimino)-1-cyclohexenyl acetonitrile, α-(isopropylsulfonyloxyimino)-1-cyclohexenyl acetonitrile, α-(n-butylsulfonyloxyimino)-1-cyclohexenyl acetonitrile, α-(methylsulfonyloxyimino)-phenyl acetonitrile, α-(methylsulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propylsulfonyloxyimino)-p-methylphenyl acetonitrile, and α-(methylsulfonyloxyimino)-p-bromophenyl acetonitrile.

Furthermore, further examples include the compounds represented by the chemical formulas shown below.

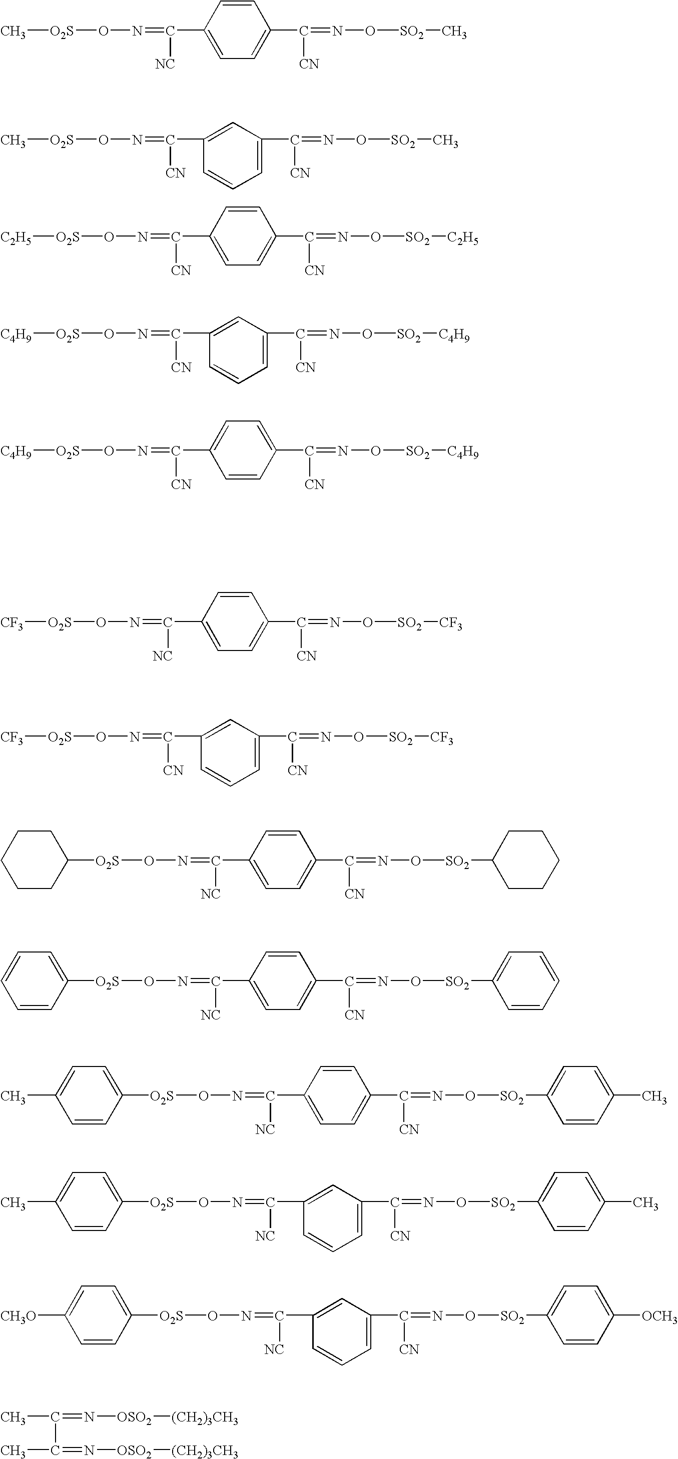

Furthermore, of the compounds represented by the aforementioned general formulas (B-2) and (B-3), examples of particularly preferred compounds include those shown below.

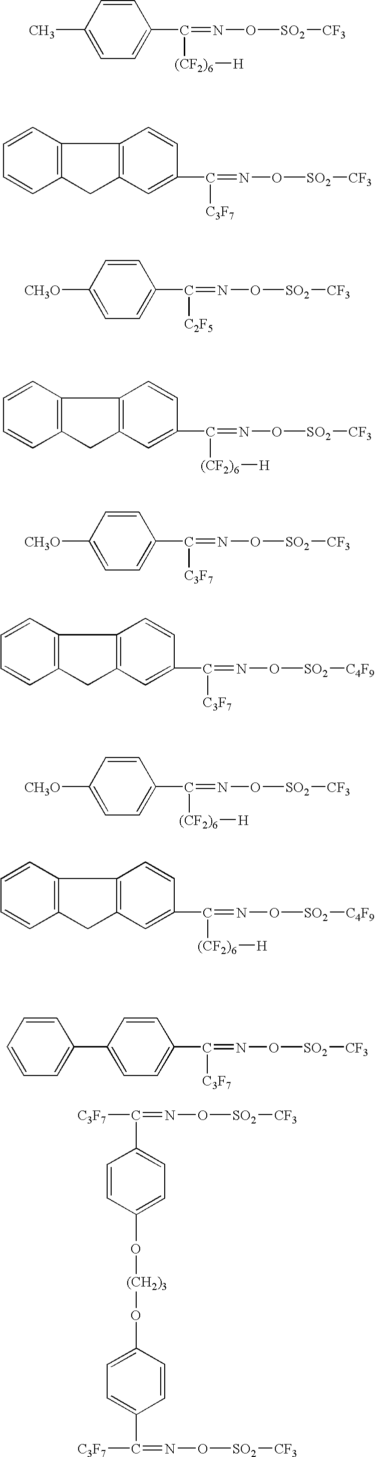

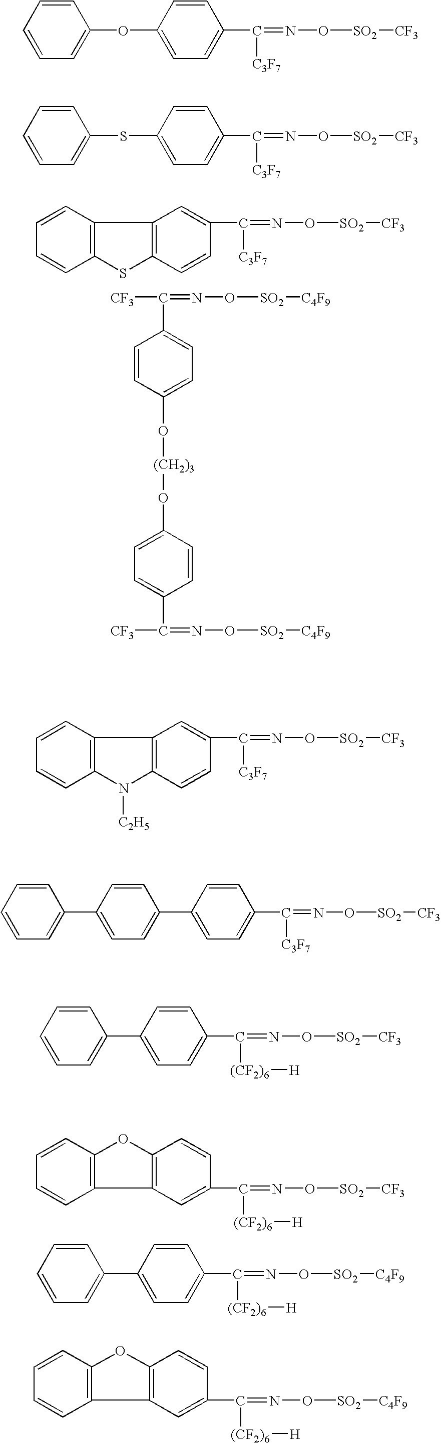

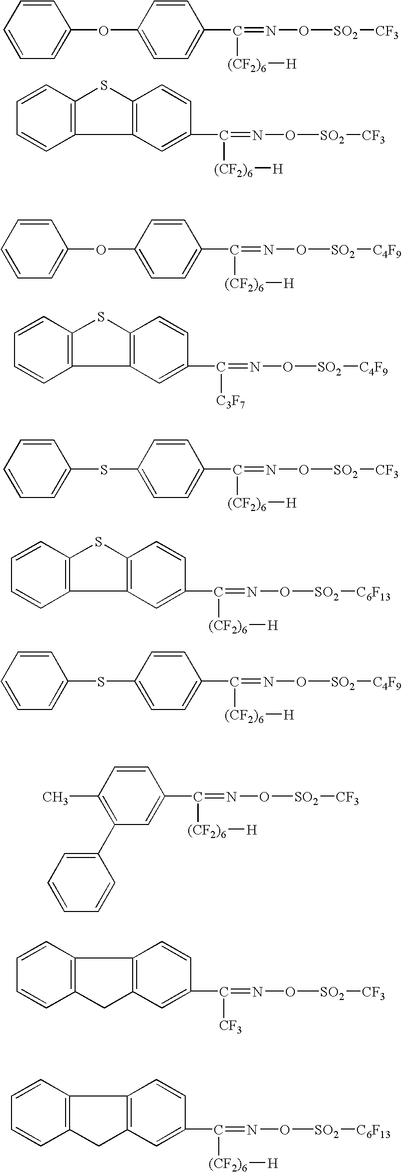

Of the above compounds, the three compounds shown below are particularly desirable.

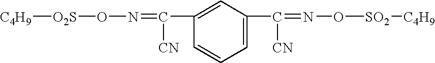

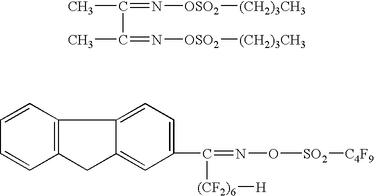

Of the various diazomethane-based acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

Furthermore, specific examples of poly(bis-sulfonyl)diazomethanes include the structures shown below, such as 1,3-bis(phenylsulfonyldiazomethylsulfonyl)propane (wherein A=3), 1,4-bis(phenylsulfonyldiazomethylsulfonyl)butane (wherein A=4), 1,6-bis(phenylsulfonyldiazomethylsulfonyl)hexane (wherein A=6), 1,10-bis(phenylsulfonyldiazomethylsulfonyl)decane (wherein A=10), 1,2-bis(cyclohexylsulfonyldiazomethylsulfonyl)ethane (wherein B=2), 1,3-bis(cyclohexylsulfonyldiazomethylsulfonyl)propane (wherein B=3), 1,6-bis(cyclohexylsulfonyldiazomethylsulfonyl)hexane (wherein B=6), and 1,10-bis(cyclohexylsulfonyldiazomethylsulfonyl)decane (wherein B=10).

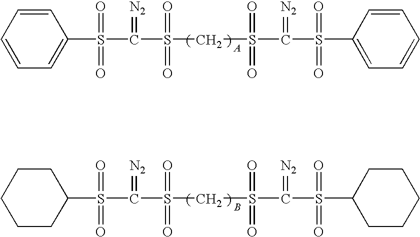

In the present invention, as the component (B), the use of an onium salt having a fluorinated alkylsulfonate ion as the anion is preferred.

As the component (B), either a single acid generator may be used alone, or a combination of two or more different acid generators may be used.

The quantity of the component (B) within the negative resist composition of the present invention is typically within a range from 0.5 to 30 parts by weight, and preferably within a range from 1 to 10 parts by weight, per 100 parts by weight of the component (A). Ensuring a quantity within this range enables satisfactory pattern formation to be conducted. Furthermore, a uniform solution is obtained, and the storage stability is also favorable, both of which are desirable.

There are no particular restrictions on the component (C), which may be selected appropriately from the various cross-linking agents used in conventional chemically amplified negative resist compositions.

Specific examples include aliphatic cyclic hydrocarbons containing a hydroxyl group and/or a hydroxyalkyl group, or oxygen-containing derivatives thereof, such as 2,3-dihydroxy-5-hydroxymethylnorbornane, 2-hydroxy-5,6-bis(hydroxymethyl)norbornane, cyclohexanedimethanol, 3,4,8(or 9)-trihydroxytricyclodecane, 2-methyl-2-adamantanol, 1,4-dioxane-2,3-diol, and 1,3,5-trihydroxycyclohexane.

Furthermore, other suitable examples include compounds produced by reacting an amino group-containing compound such as melamine, acetoguanamine, benzoguanamine, urea, ethylene urea, propylene urea or glycoluril with either formaldehyde or a combination of formaldehyde and a lower alcohol, thereby substituting the hydrogen atoms of the amino group with hydroxymethyl groups or lower alkoxymethyl groups.

Of these, compounds that use melamine are referred to as melamine-based cross-linking agents, compounds that use urea are referred to as urea-based cross-linking agents, compounds that use an alkylene urea such as ethylene urea or propylene urea are referred to as alkylene urea-based cross-linking agents, and compounds that use glycoluril are referred to as glycoluril-based cross-linking agents. The component (C) is preferably at least one compound selected from amongst melamine-based cross-linking agents, urea-based cross-linking agents, alkylene urea-based cross-linking agents, and glycoluril-based cross-linking agents, and of these, glycoluril-based cross-linking agents are particularly desirable.

Examples of melamine-based cross-linking agents include compounds obtained by reacting melamine with formaldehyde, thereby substituting the hydrogen atoms of the amino group with hydroxymethyl groups, and compounds obtained by reacting melamine with formaldehyde and a lower alcohol, thereby substituting the hydrogen atoms of the amino group with lower alkoxymethyl groups. Specific examples include hexamethoxymethylmelamine, hexaethoxymethylmelamine, hexapropoxymethylmelamine and hexabutoxybutylmelamine, and of these, hexamethoxymethylmelamine is preferred.

Examples of urea-based cross-linking agents include compounds obtained by reacting urea with formaldehyde, thereby substituting the hydrogen atoms of the amino group with hydroxymethyl groups, and compounds obtained by reacting urea with formaldehyde and a lower alcohol, thereby substituting the hydrogen atoms of the amino group with lower alkoxymethyl groups. Specific examples include bismethoxymethylurea, bisethoxymethylurea, bispropoxymethylurea and bisbutoxymethylurea, and of these, bismethoxymethylurea is preferred.

Examples of alkylene urea-based cross-linking agents include compounds represented by a general formula (III) shown below.

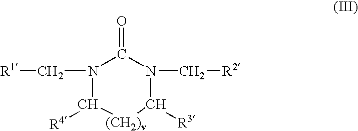

(wherein, R^{1′} and R^{2′} each represent, independently, a hydroxyl group or a lower alkoxy group, R^{3′} and R^{4′} each represent, independently, a hydrogen atom, a hydroxyl group, or a lower alkoxy group, and v represents an integer of 0, 1 or 2)

When R^{1′} and R^{2′} are lower alkoxy groups, alkoxy groups of 1 to 4 carbon atoms are preferred, and these groups may be either straight-chain or branched groups. R^{1′} and R^{2′} may be either the same or different. Compounds in which R^{1′} and R^{2′} are the same are preferred.

When R^{3′} and R^{4′} are lower alkoxy groups, alkoxy groups of 1 to 4 carbon atoms are preferred, and these groups may be either straight-chain or branched groups. R^{3′} and R^{4′} may be either the same or different. Compounds in which R^{3′} and R^{4′} are the same are preferred.

v represents an integer of 0, 1 or 2, and is preferably either 0 or 1.

As the alkylene urea-based cross-linking agent, compounds in which v is 0 (ethylene urea cross-linking agents) and/or compounds in which v is 1 (propylene urea-based cross-linking agents) are particularly preferred.

Compounds represented by the above general formula (III) can be obtained by subjecting an alkylene urea and formalin to a condensation reaction, or by further reacting the product of this reaction with a lower alcohol.

Specific examples of alkylene urea-based cross-linking agents include ethylene urea-based cross-linking agents such as mono- and/or di-hydroxymethylated ethylene urea, mono- and/or di-methoxymethylated ethylene urea, mono- and/or di-ethoxymethylated ethylene urea, mono- and/or di-propoxymethylated ethylene urea, and mono- and/or di-butoxymethylated ethylene urea; and propylene urea-based cross-linking agents such as mono- and/or di-hydroxymethylated propylene urea, mono- and/or di-methoxymethylated propylene urea, mono- and/or di-ethoxymethylated propylene urea, mono- and/or di-propoxymethylated propylene urea, and mono- and/or di-butoxymethylated propylene urea; as well as 1,3-di(methoxymethyl)-4,5-dihydroxy-2-imidazolidinone and 1,3-di(methoxymethyl)-4,5-dimethoxy-2-imidazolidinone.

Examples of glycoluril-based cross-linking agents include glycoluril derivatives in which the N-position is substituted with a hydroxyalkyl group and/or a lower alkoxyalkyl group of 1 to 4 carbon atoms. These glycoluril derivatives can be obtained by subjecting a glycoluril and formalin to a condensation reaction, or by further reacting the product of this reaction with a lower alcohol.

Specific examples of glycoluril-based cross-linking agents include mono-, di-, tri-, or tetra-hydroxymethylated glycoluril, mono-, di-, tri-, and/or tetra-methoxymethylated glycoluril, mono-, di-, tri-, and/or tetra-ethoxymethylated glycoluril, mono-, di-, tri-, and/or tetra-propoxymethylated glycoluril, and mono-, di-, tri-, and/or tetra-butoxymethylated glycoluril.

As the component (C), either a single compound may be used alone, or a combination of two or more different compounds may be used.

The blend quantity of the component (C) is preferably within a range from 3 to 30 parts by weight, even more preferably from 3 to 15 parts by weight, and most preferably from 5 to 10 parts by weight, per 100 parts by weight of the component (A). Provided this quantity is at least as large as the lower limit of the above range, cross-linking formation proceeds favorably, meaning a favorable resist pattern can be obtained. Provided the quantity is no larger than the upper limit, the storage stability of the resist coating solution is favorable, and deterioration over time in the sensitivity can be suppressed.

In the negative resist composition of the present invention, in order to improve the resist pattern shape and the post exposure stability of the latent image formed by the pattern-wise exposure of the resist layer, a nitrogen-containing organic compound (D) (hereafter referred to as the component (D)) may also be added as an optional component.

A multitude of these components (D) have already been proposed, and any of these known compounds can be used, although an aliphatic amine, and particularly a secondary aliphatic amine or tertiary aliphatic amine is preferred.

Examples of these aliphatic amines include amines in which at least one hydrogen atom of ammonia NH₃ has been substituted with an alkyl group or hydroxyalkyl group of no more than 12 carbon atoms (that is, alkylamines or alkyl alcohol amines). Specific examples of these aliphatic amines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decanylamine, and tri-n-dodecylamine; and alkyl alcohol amines such as diethanolamine, triethanolamine, diisopropanolamine, triisopropanolamine, di-n-octanolamine, and tri-n-octanolamine. Of these, alkyl alcohol amines or trialkylamines are preferred, and alkyl alcohol amines are the most desirable Amongst the various alkyl alcohol amines, triethanolamine and triisopropanolamine are the most preferred.

These compounds may be used either alone, or in combinations of two or more different compounds.

The component (D) is typically used in a quantity within a range from 0.01 to 5.0 parts by weight per 100 parts by weight of the component (A).

Furthermore, in order to prevent any deterioration in sensitivity caused by the addition of the above component (D), and improve the resist pattern shape and the post exposure stability of the latent image formed by the pattern-wise exposure of the resist layer, an organic carboxylic acid, or a phosphorus oxo acid or derivative thereof (E) (hereafter referred to as the component (E)) may also be added to the resist composition as another optional component. The component (D) and the component (E) can be used in combination, or either one can also be used alone.

Examples of suitable organic carboxylic acids include malonic acid, citric acid, malic acid, succinic acid, benzoic acid, and salicylic acid.

Examples of suitable phosphorus oxo acids or derivatives thereof include phosphoric acid or derivatives thereof such as esters, including phosphoric acid, di-n-butyl phosphate and diphenyl phosphate; phosphonic acid or derivatives thereof such as esters, including phosphonic acid, dimethyl phosphonate, di-n-butyl phosphonate, phenylphosphonic acid, diphenyl phosphonate, and dibenzyl phosphonate; and phosphinic acid or derivatives thereof such as esters, including phosphinic acid and phenylphosphinic acid, and of these, phosphonic acid is particularly preferred.

The component (E) is typically used in a quantity within a range from 0.01 to 5.0 parts by weight per 100 parts by weight of the component (A).

The negative resist composition of the present invention can be produced by dissolving the materials in an organic solvent.

The organic solvent may be any solvent capable of dissolving the various components used to generate a uniform solution, and one or more solvents selected from known materials used as the solvents for conventional chemically amplified resists can be used.

Specific examples of the solvent include lactones such as γ-butyrolactone, ketones such as acetone, methyl ethyl ketone, cyclohexanone, methyl isoamyl ketone and 2-heptanone, polyhydric alcohols and derivatives thereof such as ethylene glycol, ethylene glycol monoacetate, diethylene glycol, diethylene glycol monoacetate, propylene glycol, propylene glycol monoacetate, dipropylene glycol, or the monomethyl ether, monoethyl ether, monopropyl ether, monobutyl ether or monophenyl ether of dipropylene glycol monoacetate, cyclic ethers such as dioxane, and esters such as methyl lactate, ethyl lactate (EL), methyl acetate, ethyl acetate, butyl acetate, methyl pyruvate, ethyl pyruvate, methyl methoxypropionate, and ethyl ethoxypropionate.

These organic solvents may be used either alone, or as a mixed solvent of two or more different solvents.

Furthermore, mixed solvents produced by mixing propylene glycol monomethyl ether acetate (PGMEA) with a polar solvent are preferred. Although the blend ratio (weight ratio) in such mixed solvents can be set in accordance with factors such as the co-solubility of the PGMEA and the polar solvent, the ratio is preferably within a range from 1:9 to 9:1, and is even more preferably from 2:8 to 8:2.

More specifically, in those cases where EL is added as the polar solvent, the weight ratio PGMEA:EL is preferably within a range from 1:9 to 9:1, and is even more preferably from 2:8 to 8:2.

Furthermore, as the organic solvent, mixed solvents containing at least one of PGMEA and EL, together with γ-butyrolactone, are also preferred. In such cases, the weight ratio of the former and latter components in the mixed solvent is preferably within a range from 70:30 to 95:5.

There are no particular restrictions on the quantity used of the organic solvent, although the quantity should be set in accordance with the coating film thickness required, at a concentration that enables favorable application of the solution to a substrate or the like, and typically, the quantity of solvent is set so that the solid fraction concentration of the resist composition falls within a range from 2 to 20% by weight, and preferably from 5 to 15% by weight.

Other miscible additives can also be added to the negative resist composition of the present invention according to need, and examples include additive resins for improving the properties of the resist film, surfactants for improving the coating properties, dissolution inhibitors, plasticizers, stabilizers, colorants, halation prevention agents, and dyes.

By using the negative resist composition of the present invention, a resist pattern can be formed with favorable suppression of swelling. The reasons for this effect are thought to include the fact that the structural units (a1) and (a3) are able to suppress swelling as a result of containing an aliphatic cyclic group having a fluorinated hydroxyalkyl group, and the fact that because the composition includes the structural unit (a2) containing an alcoholic hydroxyl group with a high degree of alkali solubility, the degree of alkali solubility required for a resist can be retained.

Furthermore, the negative resist composition of the present invention also exhibits excellent resolution. It is thought that this is due to the ability of the composition to suppress swelling. Furthermore, because the resolution improves, an improvement in the exposure margin can also be expected.

Moreover, because pattern swelling can be suppressed, an improvement in the depth of focus (DOF) characteristics, and a suppression of LER (line edge roughness) can also be expected. LER refers to unevenness in the side walls of pattern lines.

In addition, because the structural units (a1) and (a3) contain aliphatic cyclic groups of high carbon density, an improvement in etching resistance is also expected.

Furthermore, an improvement in the post exposure stability of the latent image formed by the pattern-wise exposure of the resist layer can also be expected. The reason for this improvement is that because the component (A) includes the structural unit (a1) containing an aliphatic cyclic group within the main chain, steric factors mean that dehydration-condensation over time of the fluorinated hydroxyalkyl group bonded to the aliphatic cyclic group can be suppressed.

### [Method of Forming Resist Pattern]

A method of forming a resist pattern according to the present invention includes the steps of applying the negative resist composition of the present invention to a substrate, conducting a prebake, performing selective exposure, and then conducting PEB (post exposure baking), and performing alkali developing to form a resist pattern.

The method of forming a resist pattern according to the present invention can be conducted, for example, in the manner described below.

Namely, the negative resist composition described above is first applied to a substrate such as a silicon wafer using a spinner or the like, a prebake is then conducted under temperature conditions of 80 to 150° C., for a period of 40 to 120 seconds, and preferably for 60 to 90 seconds, and following selective exposure of the thus obtained film with an ArF exposure apparatus or the like, by irradiating ArF excimer laser light through a desired mask pattern, PEB (post exposure baking) is conducted under temperature conditions of 80 to 150° C., for a period of 40 to 120 seconds, and preferably for 60 to 90 seconds. Subsequently, developing is conducted using an alkali developing solution such as a 0.1 to 10% by weight aqueous solution of tetramethylammonium hydroxide. In this manner, a resist pattern that is faithful to the mask pattern can be obtained.

An organic or inorganic anti-reflective film may also be provided between the substrate and the applied layer of the resist composition.

There are no particular restrictions on the wavelength used for the exposure, and an ArF excimer laser, KrF excimer laser, F₂ excimer laser, or other radiation such as EUV (extreme ultra violet), VUV (vacuum ultra violet), EB (electron beam), X-ray or soft X-ray radiation can be used. A negative resist composition according to the present invention is particularly effective for use with an ArF excimer laser. The reason for this effectiveness is that processes using an ArF excimer laser as the exposure source require a high level of resolution, and because the negative resist composition of the present invention suppresses swelling and yields excellent resolution, it is able to meet these strict requirements. Furthermore, the negative resist composition of the present invention also provides a structure with a high degree of transparency to ArF excimer laser light.

### EXAMPLES

In the following examples 1 to 3, resins 1 to 3 described below (and manufactured by Central Glass Co., Ltd.) were used.

In the formulas shown, the numerical values shown at the bottom right of the parentheses ( ) represent the proportions (molar proportions) of each of the structural units.

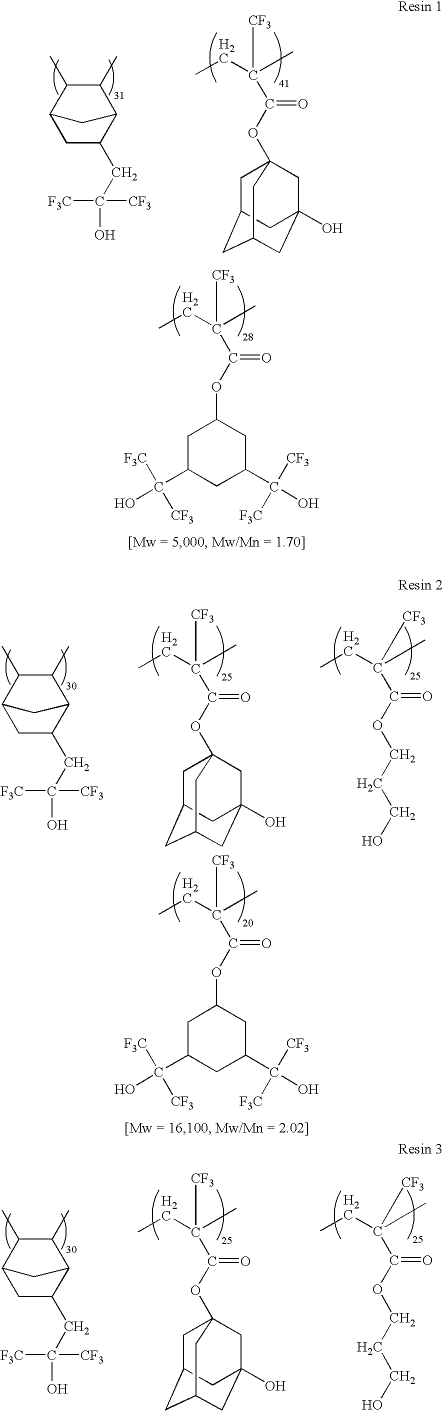

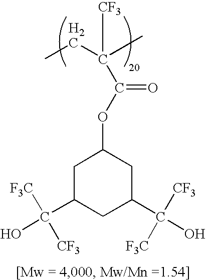

### Synthesis Example 1

### Synthesis of Comparative Resin

2.73 g of methacrylic acid, 16.5 g of ethyl (α-hydroxymethyl)acrylate, and 1.0 g of the polymerization initiator azobisisobutyronitrile were dissolved in 300 ml of THF (tetrahydrofuran). Nitrogen was bubbled through the solution for 10 minutes, and the solution was then heated for 4 hours using a 70° C. oil bath and then cooled to room temperature. Subsequently, the reaction solution was concentrated using an evaporator, the concentrated liquid was dissolved in 150 ml of THF, the resulting solution was poured into a mixed solvent containing 850 ml of heptane and 150 ml of isopropyl alcohol to precipitate the resin, and the precipitated resin was then filtered. The thus obtained resin was dried in a dryer at 40° C. for 24 hours, yielding 11.75 g of a white solid.

The chemical formula of the obtained resin (comparative resin 1) is indicated by the chemical formula below.

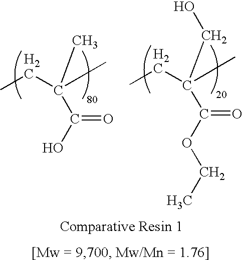

### Examples 1 to 3, Comparative Example 1

Negative resist compositions were prepared using the formulations shown in Table 1.

The abbreviations used in Table 1 have the meanings shown below

TPS-TF: triphenylsulfonium trifluoromethanesulfonate
Binder 1: tetramethoxymethylated glycoluril (MX270, manufactured by Sanwa Chemical Co., Ltd.)
Amine 1: triisopropanolamine
PGME: propylene glycol monomethyl ether

TABLE 1

| | Component (A) | Component (B) | Component (C) | Component (D) | Organic solvent |
|---|---|---|---|---|---|
| | [parts by weight] | [parts by weight] | [parts by weight] | [parts by weight] | [parts by weight] |
| Example 1 | Resin 1 | TPS-TF | Binder 1 | Amine 1 | PGME |
| | [100] | [2.0] | [5.0] | [0.4] | [1150] |
| Example 2 | Resin 2 | TPS-TF | Binder 1 | Amine 1 | PGME |
| | [100] | [2.0] | [5.0] | [0.4] | [1150] |
| Example 3 | Resin 3 | TPS-TF | Binder 1 | Amine 1 | PGME |
| | [100] | [2.0] | [5.0] | [0.4] | [1150] |
| Comparative | Comparative | TPS-TF | Binder 1 | Amine 1 | PGME |
| example 1 | resin 1 [100] | [2.0] | [5.0] | [0.4] | [1150] |

Using each of the thus obtained negative resist compositions, an evaluation was conducted in the manner described below.

An organic anti-reflective film composition AR-19 (a product name, manufactured by Shipley Co., Ltd.) was applied to the surface of a substrate (an 8-inch silicon wafer) using a spinner, and the composition was then baked and dried on a hotplate at 215° C. for 90 seconds, thereby forming an organic anti-reflective film with a film thickness of 82 nm. The negative resist composition prepared above was then applied uniformly to the surface of this organic anti-reflective film using a spinner, and was then prebaked (PAB) and dried on a hotplate under the conditions shown below in Table 2, thereby forming a resist layer with a film thickness of 200 nm. The thus obtained resist layer was then selectively exposed with an ArF excimer laser (193 nm) through a mask pattern, using an ArF exposure apparatus NSR-S302 (manufactured by Nikon Corporation, NA (numerical aperture)=0.60, 2/3 annular illumination).

A PEB treatment was then conducted under the conditions shown below in Table 2, and the resist layer was subjected to puddle development for 60 seconds at 23° C. in a 2.38% by weight aqueous solution of tetramethylammonium hydroxide, and was then rinsed for 30 seconds with pure water and shaken dry, completing formation of a 1:1 line and space pattern (LS). For the examples 1 to 3, the sensitivity during formation of a 140 nm LS pattern was used as the EOP value, whereas for the comparative example 1, the sensitivity during formation of a 160 nm LS pattern was used as the EOP value.

Furthermore, the critical resolution resolvable at this exposure dose EOP (namely, the resolution) was also determined.

Moreover, the cross-sectional shape of the formed pattern was inspected using a scanning electron microscope, and the level of swelling and the pattern shape were evaluated using the following criteria.

A: the resist pattern had no swelling and exhibited a high degree of cross-sectional rectangular formability
B: the resist pattern showed slight swelling within the top portions, but this swelling was of a level unlikely to cause any practical problems, and the cross-sectional rectangular formability was favorable
C: the resist pattern exhibited severe swelling

The results are shown in Table 3.

TABLE 2

| | PAB | PEB |
|---|---|---|
| Example 1 | 110° C./60 seconds | 120° C./60 seconds |
| Example 2 | 80° C./60 seconds | 100° C./60 seconds |
| Example 3 | 80° C./60 seconds | 100° C./60 seconds |
| Comparative example 1 | 80° C./60 seconds | 100° C./60 seconds |

TABLE 3

| | EOP | Resolution | Swelling and Shape |
|---|---|---|---|
| Example 1 | 29 mJ/cm² | 120 nm LS | A |
| Example 2 | 23 mJ/cm² | 120 nm LS | B |
| Example 3 | 27 mJ/cm² | 120 nm LS | B |
| Comparative example 1 | 20 mJ/cm² | 160 nm LS | C |

As shown in Table 3, use of the negative resist compositions of examples 1 to 3 according to the present invention enabled the formation of resist patterns in which swelling had been suppressed. Furthermore, the resolution of the patterns was also excellent.

In contrast, the comparative example 1, which used a resin component containing carboxyl groups, suffered severe swelling of the resist pattern, and also exhibited poor resolution.

### INDUSTRIAL APPLICABILITY

The present invention enables resist pattern swelling to be suppressed, and can be applied to a negative resist composition and a method of forming a resist pattern.

1. A negative resist composition, comprising: an alkali-soluble resin component (A); an acid generator component (B) that generates acid upon exposure; and a cross-linking agent component (C), wherein
said alkali-soluble resin component (A) is a copolymer (A1) comprising a structural unit (a1) containing, within a main chain, an aliphatic cyclic group having a fluorinated hydroxyalkyl group, a structural unit (a2) derived from an acrylate ester which contains a hydroxyl group-containing chain-like or cyclic alkyl group and have a fluoroalkyl group or fluorine atom bonded to an α-position, and a structural unit (a3) derived from an acrylate ester which contains an aliphatic cyclic group having a fluorinated hydroxyalkyl group and has a fluoroalkyl group or fluorine atom bonded to an α-position.

2. A negative resist composition according to claim 1, wherein said structural unit (a1) comprises a structural unit (a1-1) represented by a general formula (a1-1) shown below: 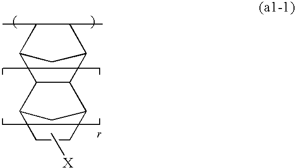
[wherein, X represents a fluorinated hydroxyalkyl group, and r is either 0 or 1].

3. A negative resist composition according to claim 2, wherein said group X is a group represented by a general formula (a1-1-1) shown below: 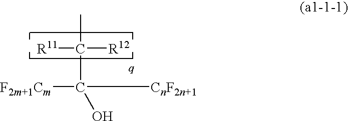
[wherein, R¹¹ and R¹² each represent, independently, a hydrogen atom or a lower alkyl group, m and n each represent, independently, an integer from 1 to 5, and q represents an integer from 1 to 5].

4. A negative resist composition according to any one of claim 1 through claim 3, wherein said structural unit (a2) comprises a structural unit (a2-1) represented by a general formula (a2-1) shown below: 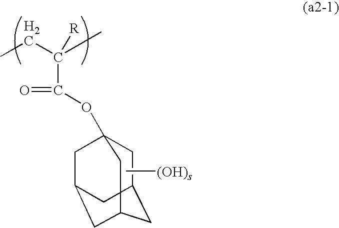
[wherein, R represents a fluoroalkyl group or a fluorine atom, and s represents an integer from 1 to 3].

5. A negative resist composition according to any one of claim 1 through claim 3, wherein said structural unit (a2) comprises a structural unit (a2-2) represented by a general formula (a2-2) shown below: 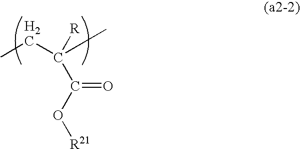
[wherein, R represents a fluoroalkyl group or a fluorine atom, and R²¹ represents a hydroxyalkyl group].

6. A negative resist composition according to claim 5, wherein said structural unit (a2) comprises both said structural unit (a2-1) and said structural unit (a2-2).

7. A negative resist composition according to any one of claim 1 through claim 3, wherein said structural unit (a3) comprises a structural unit (a3-1) represented by a general formula (a3-1) shown below: 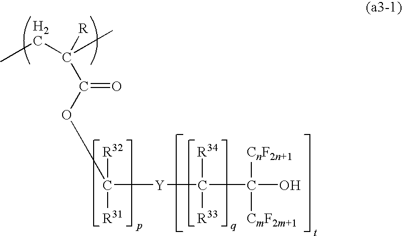
[wherein, R represents a fluoroalkyl group or a fluorine atom, R³¹ to R³⁴ each represent, independently, a hydrogen atom or a lower alkyl group, p and q each represent, independently, either 0 or an integer from 1 to 3, m and n each represent, independently, an integer from 1 to 5, t represents an integer from 1 to 3, and Y represents an aliphatic cyclic group].

8. A negative resist composition according to any one of claim 1 through claim 3, wherein within said copolymer (A1), a proportion of said structural unit (a1) is within a range from 10 to 70 mol %, a proportion of said structural unit (a2) is within a range from 10 to 80 mol %, and a proportion of said structural unit (a3) is within a range from 5 to 50 mol %.

9. A negative resist composition according to any one of claim 1 through claim 3, wherein said cross-linking agent component (C) is one or more compounds selected from the group consisting of melamine-based cross-linking agents, urea-based cross-linking agents, alkylene urea-based cross-linking agents, and glycoluril-based cross-linking agents.

10. A negative resist composition according to any one of claim 1 through claim 3, further comprising a nitrogen-containing organic compound (D).

11. A method of forming a resist pattern, comprising the steps of applying a negative resist composition according to any one of claim 1 through claim 3 to a substrate, conducting a prebake, performing selective exposure, conducting PEB (post exposure baking), and performing alkali developing to form a resist pattern.
